(19) United States
(12) Patent Application Publication
(10) Pub. No.: US 2002/0168003 A1
(43) Pub. Date: Nov. 14, 2002

(54) System and method of communicating high rate pulse signals in a multipath environment

(76) Inventor: James L. Richards, Fayettville, TN (US)

Correspondence Address: James S. Finn, 7057 Old Madison Pike, Huntsville, AL, 35806, US

(21) Appl. No.: 10/075,913

(22) Filed: Nov. 13, 2001

Related U.S. Application Data
(60) Provisional application No. 60/248,142, filed on Nov. 13, 2000.

(51) Int. Cl. H03K 7/04

(52) U.S. Cl. 375/239; 375/219

(57) ABSTRACT

A high rate impulse radio communication system where the modulation period is shorter than the multipath decay period and relates to the placement of pulses in a sequence of pulses such that pulses subsequent to the first pulse are placed in time at locations that are optimum based on the multipath response of the channel.

### CROSS REFERENCE TO CO-PENDING APPLICATIONS

This application claims priority to provisional patent application entitled “System and Method of Communicating High Rate Pulse Signals in a Multipath Environment” filed Nov. 13, 2000, serial No. 60/248,142, with all common inventors with the present application and common assignee of the present application.

### BACKGROUND OF THE INVENTION

1. Field of the Invention

This present invention relates to a system and method of communicating high rate pulse signals in a multipath environment. Still more particularly the present invention relates to a system and method of communicating high rate pulse signals in a multipath environment for significant improvements in impulse radio systems.

2. Background of the Invention and Related Art

When high rate pulse signals are sent in a heavy multipath environment, the multipath response from early pulses arrives coincident with later pulses reducing error margin or in heavy multipath, substantially swamping the desired signal.

Multipath results from potentially thousands of reflectors in an office building. The detail structure of multipath may be substantially decorrelated by movement of only one or two feet. Thus any given measurement of multipath may not be valid for long where even slow pedestrian mobility may be involved. Moreover, even fixed locations are subject to motion of objects in the environment (i.e., multipath structure may not even be stable for fixed devices since people, furniture, and equipment are subject to motion and significantly affect the environmental multipath).

Prior art impulse radio systems overcome multipath by transmitting pulses at a time interval longer than the multipath decay time such that subsequent pulses receive insignificant energy from the multipath response of prior pulses. This presents a practical data rate limit related to the multipath decay profile in a particular scenario and the signal to noise requirements of the impulse modulation used. There is an insatiable need for ever increasing data rates in the present wireless market place to serve consumer and commercial information technology needs.

Thus, there is a need in the art to provide new methods of improving signal reception of high rate pulses in high multipath environments.

### SUMMARY OF THE INVENTION

The present invention relates to impulse radio communication systems and more particularly to high rate communication systems where the modulation period is shorter than the multipath decay period and the present invention relates to the placement of pulses in a sequence of pulses such that pulses subsequent to the first pulse are placed in time at locations that are optimum based on the multipath response of the channel.

In one embodiment of the present invention, the pulses are placed at multipath zero crossings or null response points in order to minimize coupling between early pulses and later pulses.

In another embodiment of the present invention, later pulses are placed at maximum response points of earlier pulses and are then separated mathematically by solving statistical simultaneous equations. This second embodiment also provides efficient signal enhancement by adding the energy of the later multipath maximum with the energy of the earlier direct pulse.

In a third embodiment, the pulses are sent in predetermined positions and the receiver measures cross coupling from each pulse time to later pulse times. These cross coupling values are then used to separate the modulation states from each pulse transmission.

In a further embodiment, the pulses are grouped into bursts of closely spaced and carefully coordinated pulses followed by times of no transmission to allow for the decay of multipath energy between bursts, thus simplifying the determination of modulation and allowing for reception between pulse bursts.

In a further embodiment, the pulse placement is determined by measuring the channel at a second transceiver, determining the optimum pulse placement, and communicating the optimum placement to transceiver 1. Alternatively transceiver 1 may use its own channel measurements from signals received from transceiver 2 to determine optimum placement points and then notify transceiver 2 of these positions. In an additional embodiment, a method is disclosed whereby transceiver 2 efficiently searches for the pulse signals without notification of their position.

In a further embodiment, pulse cross coupling values are determined adaptively to maintain operation in the presence of scenario dynamics either from motion of transmitters and receivers or from motion of objects in the environment.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1A illustrates a representative Gaussian Monocycle waveform in the time domain.

FIG. 1B illustrates the frequency domain amplitude of the Gaussian Monocycle of FIG. 1A.

FIG. 2A illustrates a pulse train comprising pulses as in FIG. 1A.

FIG. 2B illustrates the frequency domain amplitude of the waveform of FIG. 2A.

FIG. 3 illustrates the frequency domain amplitude of a sequence of time coded pulses.

FIG. 4 illustrates a typical received signal and interference signal.

FIG. 5A illustrates a typical geometrical configuration giving rise to multipath received signals.

FIG. 5B illustrates exemplary multipath signals in the time domain.

FIGS. 5C-5E illustrate a signal plot of various multipath environments.

FIG. 5F illustrates the Rayleigh fading curve associated with non-impulse radio transmissions in a multipath environment.

FIG. 5G illustrates a plurality of multipaths with a plurality of reflectors from a transmitter to a receiver.

FIG. 5H graphically represents signal strength as volts vs. time in a direct path and multipath environment.

FIG. 6 illustrates a representative impulse radio transmitter functional diagram.

FIG. 7 illustrates a representative impulse radio receiver functional diagram.

FIG. 8A illustrates a representative received pulse signal at the input to the correlator.

FIG. 8B illustrates a sequence of representative impulse signals in the correlation process.

FIG. 8C illustrates the output of the correlator for each of the time offsets of FIG. 8B.

FIG. 9 is an illustration depicting a typical received impulse signal voltage vs. time plot including both the direct path and the multipath components.

FIG. 10 illustrates an exemplary system wherein two pulses are to be sent in rapid succession in accordance with the present invention.

FIG. 11 illustrates the placement of two pulses such that the second pulse is coincident with a zero crossing of the response to the first pulse.

FIG. 12 illustrates the timing relationship wherein plot AA represents the received signal from the first pulse and plot BB represents the received signal from the second pulse, and plot CC represents the sampling pulse timing relative to the received signals.

FIG. 13 illustrates that either signal AA or signal BB may be flipped in sign, with BB flipped in this illustration.

FIG. 13a illustrates that the second pulse may be arbitrarily placed.

FIG. 13b is a modified version of FIG. 13a where the second pulse is inverted.

FIG. 14 is a simplified version of FIG. 12 for illustration of how these ambiguities can be resolved with a resulting improvement in signal to noise over a simple flip modulation case.

FIG. 15 is an exemplary block diagram of a receiver system in accordance with the present invention.

FIG. 16 is an exemplary block diagram of a feed forward demodulation function in accordance with the present invention.

FIG. 17 is a block diagram of a parallel detection system in accordance with the present invention.

FIG. 18 is a block diagram of an exemplary matching function shown in FIG. 17 in accordance with the present invention.

FIG. 19 is a block diagram of a transceiver system in accordance with the present invention.

FIG. 20 is a flow diagram of a method in accordance with the present invention.

### DETAILED DESCRIPTION OF THE EMBODIMENTS

Overview of the Invention

The present invention will now be described more fully in detail with reference to the accompanying drawings, in which the preferred embodiments of the invention are shown. This invention should not, however, be construed as limited to the embodiments set forth herein; rather, they are provided so that this disclosure will be thorough and complete and will fully convey the scope of the invention to those skilled in art. Like numbers refer to like elements throughout.

Recent advances in communications technology have enabled an emerging, revolutionary ultra wideband technology (UWB) called impulse radio communications systems (hereinafter called impulse radio). To better understand the benefits of impulse radio to the present invention, the following review of impulse radio follows Impulse radio was first fully described in a series of patents, including U.S. Pat. No. 4,641,317 (issued Feb. 3, 1987), U.S. Pat. No. 4,813,057 (issued Mar. 14, 1989), U.S. Pat. No. 4,979,186 (issued Dec. 18, 1990) and U.S. Pat. No. 5,363,108 (issued Nov. 8, 1994) to Larry W. Fullerton. A second generation of impulse radio patents includes U.S. Pat. No. 5,677,927 (issued Oct. 14, 1997), U.S. Pat. No.5,687,169 (issued Nov. 11, 1997) and co-pending application Ser. No. 08/761,602 (filed Dec. 6, 1996) to Fullerton et al.

Uses of impulse radio systems are described in U.S. patent application Ser. No. 09/332,502, entitled, “System and Method for Intrusion Detection using a Time Domain Radar Array” and U.S. patent application Ser. No.09/332,503, entitled, “Wide Area Time Domain Radar Array” both filed on Jun. 14, 1999 and both of which are assigned to the assignee of the present invention. All of the above patent documents are incorporated herein by reference.

Impulse Radio Basics

Impulse radio refers to a radio system based on short, low duty cycle pulses. An ideal impulse radio waveform is a short Gaussian monocycle. As the name suggests, this waveform attempts to approach one cycle of radio frequency (RF) energy at a desired center frequency. Due to implementation and other spectral limitations, this waveform may be altered significantly in practice for a given application. Most waveforms with enough bandwidth approximate a Gaussian shape to a useful degree.

Impulse radio can use many types of modulation, including AM, time shift (also referred to as pulse position) and M-ary versions. The time shift method has simplicity and power output advantages that make it desirable. In this document, the time shift method is used as an illustrative example.

In impulse radio communications, the pulse-to-pulse interval can be varied on a pulse-by-pulse basis by two components: an information component and a code component. Generally, conventional spread spectrum systems employ codes to spread the normally narrow band information signal over a relatively wide band of frequencies. A conventional spread spectrum receiver correlates these signals to retrieve the original information signal. Unlike conventional spread spectrum systems, in impulse radio communications codes are not needed for energy spreading because the monocycle pulses themselves have an inherently wide bandwidth. Instead, codes are used for channelization, energy smoothing in the frequency domain, resistance to interference, and reducing the interference potential to nearby receivers.

The impulse radio receiver is typically a direct conversion receiver with a cross correlator front end which coherently converts an electromagnetic pulse train of monocycle pulses to a baseband signal in a single stage. The baseband signal is the basic information signal for the impulse radio communications system. It is often found desirable to include a subcarrier with the baseband signal to help reduce the effects of amplifier drift and low frequency noise. The subcarrier that is typically implemented alternately reverses modulation according to a known pattern at a rate faster than the data rate. This same pattern is used to reverse the process and restore the original data pattern just before detection. This method permits alternating current (AC) coupling of stages, or equivalent signal processing to eliminate direct current (DC) drift and errors from the detection process. This method is described in detail in U.S. Pat. No. 5,677,927 to Fullerton et al.

In impulse radio communications utilizing time shift modulation, each data bit typically time position modulates many pulses of the periodic timing signal. This yields a modulated, coded timing signal that comprises a train of pulses for each single data bit. The impulse radio receiver integrates multiple pulses to recover the transmitted information.

Waveforms

Impulse radio refers to a radio system based on short, low duty cycle pulses. In the widest bandwidth embodiment, the resulting waveform approaches one cycle per pulse at the center frequency. In more narrow band embodiments, each pulse consists of a burst of cycles usually with some spectral shaping to control the bandwidth to meet desired properties such as out of band emissions or in-band spectral flatness, or time domain peak power or burst off time attenuation.

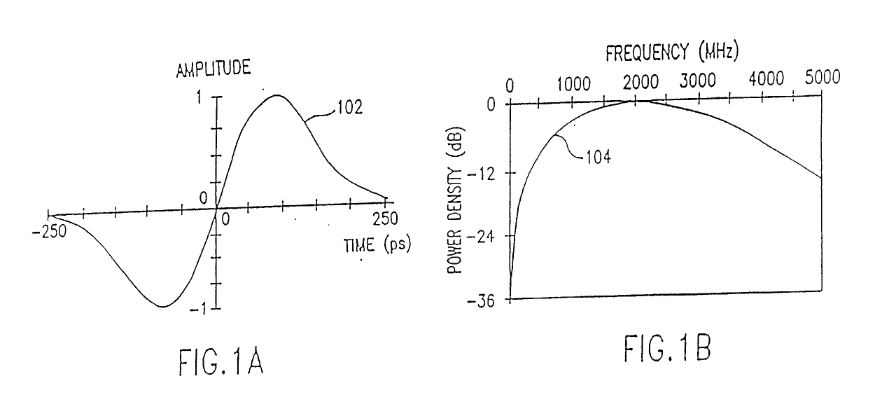

For system analysis purposes, it is convenient to model the desired waveform in an ideal sense to provide insight into the optimum behavior for detail design guidance. One such waveform model that has been useful is the Gaussian monocycle as shown in FIG. 1A. This waveform is representative of the transmitted pulse produced by a step function into an ultra-wideband antenna. The basic equation normalized to a peak value of 1 is as follows:

$${f}_{mono} ( t ) = \sqrt{e} ( \frac{t}{σ} ) {ⅇ}^{\frac{- {t}^{2}}{2 {σ}^{2}}}$$

Where,

σ is a time scaling parameter,

t is time,

fₘₒₙₒ(t) is the waveform voltage, and

e is the natural logarithm base.

The frequency domain spectrum of the above waveform is shown in FIG. 1B. The corresponding equation is:

$${F}_{mono} ( f ) = {( 2 π )}^{\frac{3}{2}} σ f {ⅇ}^{- 2 {( π σ f )}^{2}}$$

The center frequency (f_{c}), or frequency of peak spectral density is:

$${f}_{c} = \frac{1}{2 π σ}$$

These pulses, or bursts of cycles, may be produced by methods described in the patents referenced above or by other methods that are known to one of ordinary skill in the art. Any practical implementation will deviate from the ideal mathematical model by some amount. In fact, this deviation from ideal may be substantial and yet yield a system with acceptable performance. This is especially true for microwave implementations, where precise waveform shaping is difficult to achieve. These mathematical models are provided as an aid to describing ideal operation and are not intended to limit the invention. In fact, any burst of cycles that adequately fills a given bandwidth and has an adequate on-off attenuation ratio for a given application will serve the purpose of this invention.

A Pulse Train

Impulse radio systems can deliver one or more data bits per pulse; however, impulse radio systems more typically use pulse trains, not single pulses, for each data bit. As described in detail in the following example system, the impulse radio transmitter produces and outputs a train of pulses for each bit of information.

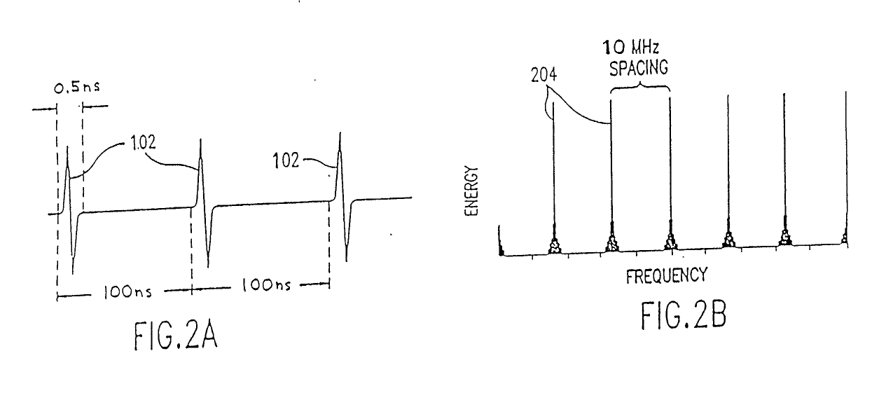

Prototypes have been built which have pulse repetition frequencies including 0.7 and 10 megapulses per second (Mpps, where each megapulse is 10⁶ pulses). FIGS. 2A and 2B are illustrations of the output of a typical 10 Mpps system with uncoded, unmodulated, 0.5 nanosecond (ns) pulses 102. FIG. 2A shows a time domain representation of this sequence of pulses 102. FIG. 2B, which shows 60 MHZ at the center of the spectrum for the waveform of FIG. 2A, illustrates that the result of the pulse train in the frequency domain is to produce a spectrum comprising a set of lines 204 spaced at the frequency of the 10 Mpps pulse repetition rate. When the full spectrum is shown, the envelope of the line spectrum follows the curve of the single pulse spectrum 104 of FIG. 1B. For this simple uncoded case, the power of the pulse train is spread among roughly two hundred comb lines. Each comb line thus has a small fraction of the total power and presents much less of an interference problem to a receiver sharing the band.

It can also be observed from FIG. 2A that impulse radio systems typically have very low average duty cycles resulting in average power significantly lower than peak power. The duty cycle of the signal in the present example is 0.5%, based on a 0.5 ns pulse in a 100 ns interval.

Coding for Energy Smoothing and Channelization

For high pulse rate systems, it may be necessary to more finely spread the spectrum than is achieved by producing comb lines. This may be done by non-uniformly positioning each pulse relative to its nominal position according to a code such as a pseudo random code.

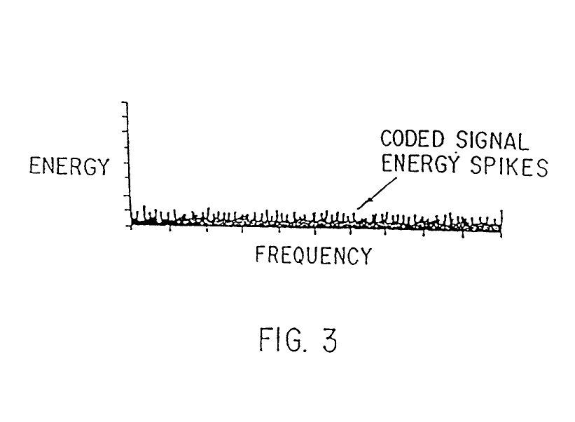

FIG. 3 is a plot illustrating the impact of a pseudo-noise (PN) code dither on energy distribution in the frequency domain (A pseudo-noise, or PN code is a set of time positions defining pseudo-random positioning for each pulse in a sequence of pulses). FIG. 3, when compared to FIG. 2B, shows that the impact of using a PN code is to destroy the comb line structure and spread the energy more uniformly. This structure typically has slight variations that are characteristic of the specific code used.

Coding also provides a method of establishing independent communication channels using impulse radio. Codes can be designed to have low cross correlation such that a pulse train using one code will seldom collide on more than one or two pulse positions with a pulses train using another code during any one data bit time. Since a data bit may comprise hundreds of pulses, this represents a substantial attenuation of the unwanted channel.

Modulation

Any aspect of the waveform can be modulated to convey information. Amplitude modulation, phase modulation, frequency modulation, time shift modulation and M-ary versions of these have been proposed. Both analog and digital forms have been implemented. Of these, digital time shift modulation has been demonstrated to have various advantages and can be easily implemented using a correlation receiver architecture.

Digital time shift modulation can be implemented by shifting the coded time position by an additional amount (that is, in addition to code dither) in response to the information signal. This amount is typically very small relative to the code shift. In a 10 Mpps system with a center frequency of 2 GHz., for example, the code may command pulse position variations over a range of 100 ns; whereas, the information modulation may only deviate the pulse position by 150 ps.

Thus, in a pulse train of n pulses, each pulse is delayed a different amount from its respective time base clock position by an individual code delay amount plus a modulation amount, where n is the number of pulses associated with a given data symbol digital bit.

Modulation further smooths the spectrum, minimizing structure in the resulting spectrum.

Reception and Demodulation

Clearly, if there were a large number of impulse radio users within a confined area, there might be mutual interference. Further, while coding minimizes that interference, as the number of users rises, the probability of an individual pulse from one user's sequence being received simultaneously with a pulse from another user's sequence increases. Impulse radios are able to perform in these environments, in part, because they do not depend on receiving every pulse. The impulse radio receiver performs a correlating, synchronous receiving function (at the RF level) that uses a statistical sampling and combining of many pulses to recover the transmitted information.

Impulse radio receivers typically integrate from 1 to 1000 or more pulses to yield the demodulated output. The optimal number of pulses over which the receiver integrates is dependent on a number of variables, including pulse rate, bit rate, interference levels, and range.

Interference Resistance

Besides channelization and energy smoothing, coding also makes impulse radios highly resistant to interference from all radio communications systems, including other impulse radio transmitters. This is critical as any other signals within the band occupied by an impulse signal potentially interfere with the impulse radio. Since there are currently no unallocated bands available for impulse systems, they must share spectrum with other conventional radio systems without being adversely affected. The code helps impulse systems discriminate between the intended impulse transmission and interfering transmissions from others.

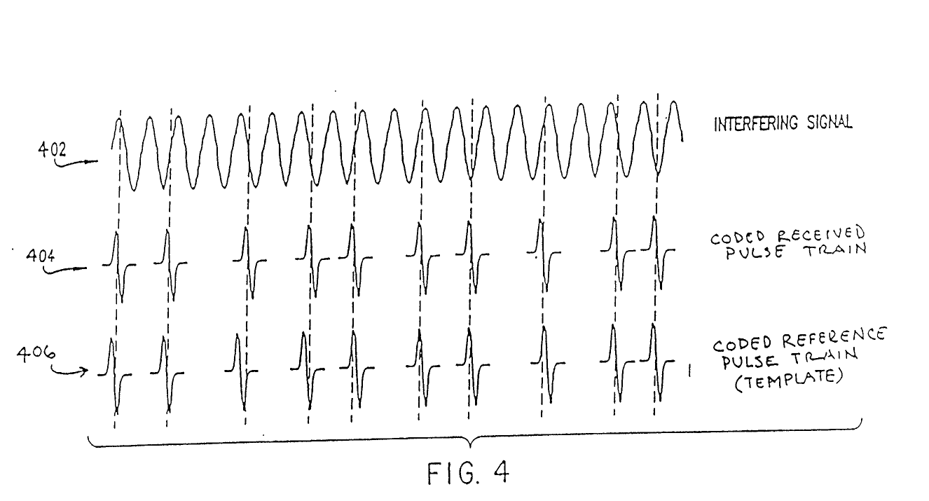

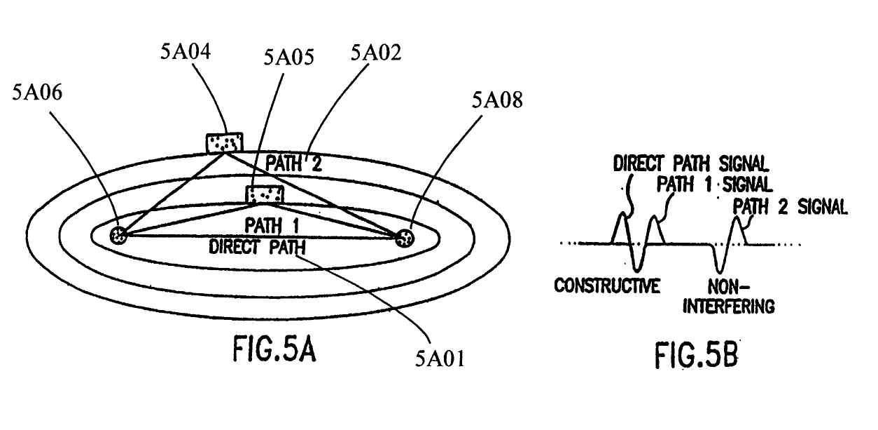

FIG. 4 illustrates the result of a narrow band sinusoidal interference signal 402 overlaying an impulse radio signal 404. At the impulse radio receiver, the input to the cross correlation would include the narrow band signal 402, as well as the received ultrawide-band impulse radio signal 404. The input is sampled by the cross correlator with a code dithered template signal 406. Without coding, the cross correlation would sample the interfering signal 402 with such regularity that the interfering signals could cause significant interference to the impulse radio receiver. However, when the transmitted impulse signal is encoded with the code dither (and the impulse radio receiver template signal 406 is synchronized with that identical code dither) the correlation samples the interfering signals non-uniformly. The samples from the interfering signal add incoherently, increasing roughly according to square root of the number of samples integrated; whereas, the impulse radio samples add coherently, increasing directly according to the number of samples integrated. Thus, integrating over many pulses overcomes the impact of interference.

Processing Gain

Impulse radio is resistant to interference because of its large processing gain. For typical spread spectrum systems, the definition of processing gain, which quantifies the decrease in channel interference when wide-band communications are used, is the ratio of the bandwidth of the channel to the bit rate of the information signal. For example, a direct sequence spread spectrum system with a 10 KHz information bandwidth and a 10 MHz channel bandwidth yields a processing gain of 1000 or 30 dB. However, far greater processing gains are achieved by impulse radio systems, where the same 10 KHz information bandwidth is spread across a much greater 2 GHz channel bandwidth, resulting in a theoretical processing gain of 200,000 or 53 dB.

Capacity

It has been shown theoretically, using signal to noise arguments, that thousands of simultaneous voice channels are available to an impulse radio system as a result of the exceptional processing gain, which is due to the exceptionally wide spreading bandwidth.

For a simplistic user distribution, with N interfering users of equal power equidistant from the receiver, the total interference signal to noise ratio as a result of these other users can be described by the following equation:

$${V}_{tot}^{2} = \frac{N {σ}^{2}}{\sqrt{Z}}$$

Where V²ₜₒₜ is the total interference signal to noise ratio variance, at the receiver;

N is the number of interfering users;

σ² is the signal to noise ratio variance resulting from one of the interfering signals with a single pulse cross correlation; and

Z is the number of pulses over which the receiver integrates to recover the modulation.

This relationship suggests that link quality degrades gradually as the number of simultaneous users increases. It also shows the advantage of integration gain. The number of users that can be supported at the same interference level increases by the square root of the number of pulses integrated.

Multipath and Propagation

One of the striking advantages of impulse radio is its resistance to multipath fading effects. Conventional narrow band systems are subject to multipath through the Rayleigh fading process, where the signals from many delayed reflections combine at the receiver antenna according to their seemingly random relative phases. This results in possible summation or possible cancellation, depending on the specific propagation to a given location. This situation occurs where the direct path signal is weak relative to the multipath signals, which represents a major portion of the potential coverage of a radio system. In mobile systems, this results in wild signal strength fluctuations as a function of distance traveled, where the changing mix of multipath signals results in signal strength fluctuations for every few feet of travel.

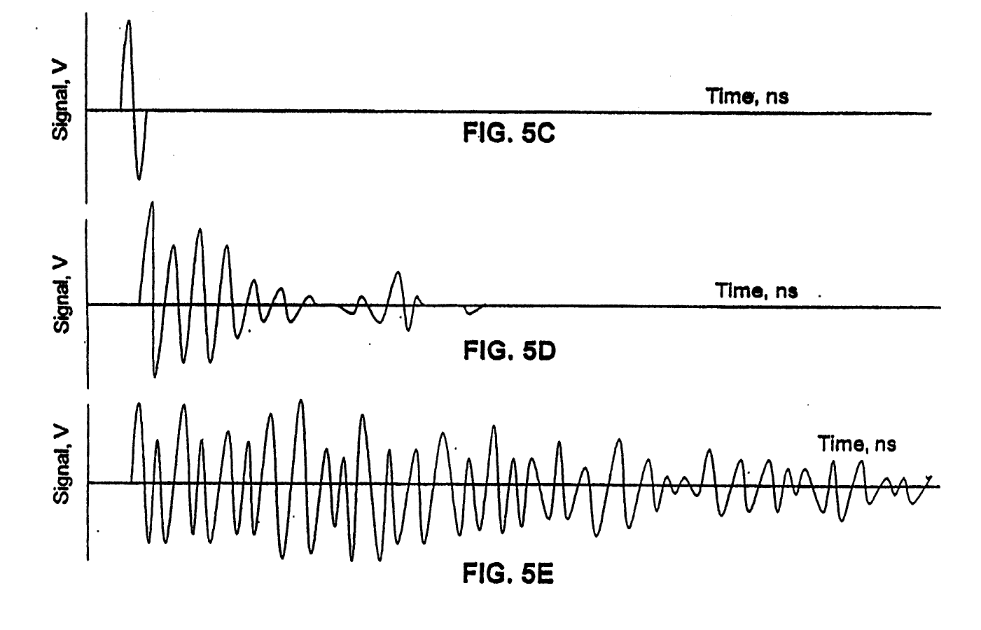

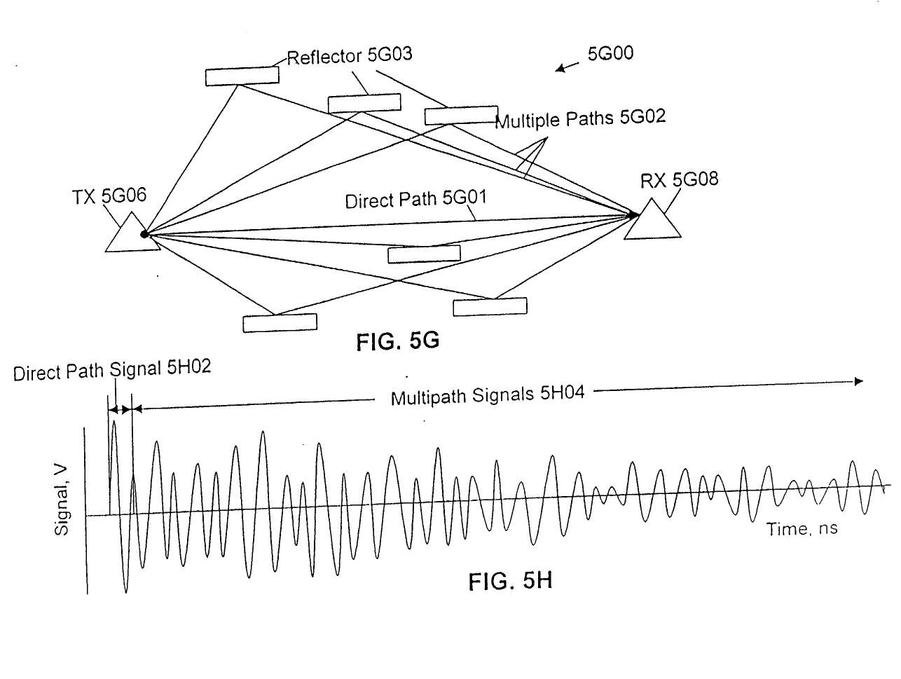

Impulse radios, however, can be substantially resistant to these effects. Impulses arriving from delayed multipath reflections typically arrive outside of the correlation time and thus can be ignored. This process is described in detail with reference to FIGS. 5A and 5B. In FIG. 5A, three propagation paths are shown. The direct path representing the straight-line distance between the transmitter and receiver is the shortest. Path 1 represents a grazing multipath reflection, which is very close to the direct path. Path 2 represents a distant multipath reflection. Also shown are elliptical (or, in space, ellipsoidal) traces that represent other possible locations for reflections with the same time delay.

FIG. 5B represents a time domain plot of the received waveform from this multipath propagation configuration. This figure comprises three doublet pulses as shown in FIG. 1A. The direct path signal is the reference signal and represents the shortest propagation time. The path 1 signal is delayed slightly and actually overlaps and enhances the signal strength at this delay value. Note that the reflected waves are reversed in polarity. The path 2 signal is delayed sufficiently that the waveform is completely separated from the direct path signal. If the correlator template signal is positioned at the direct path signal, the path 2 signal will produce no response. It can be seen that only the multipath signals resulting from very close reflectors have any effect on the reception of the direct path signal. The multipath signals delayed less than one quarter wave (one quarter wave is about 1.5 inches, or 3.5 cm at 2 GHz center frequency) are the only multipath signals that can attenuate the direct path signal. This region is equivalent to the first Fresnel zone familiar to narrow band systems designers. Impulse radio, however, has no further nulls in the higher Fresnel zones. The ability to avoid the highly variable attenuation from multipath gives impulse radio significant performance advantages.

FIG. 5A illustrates a typical multipath situation, such as in a building, where there are many reflectors 5A04, 5A05 and multiple propagation paths 5A02, 5A01. In this figure, a transmitter TX 5A06 transmits a signal that propagates along the multiple propagation paths 5A02, 5A04 to receiver RX 5A08, where the multiple reflected signals are combined at the antenna.

FIG. 5B illustrates a resulting typical received composite pulse waveform resulting from the multiple reflections and multiple propagation paths 5A01, 5A02. In this figure, the direct path signal 5A01 is shown as the first pulse signal received. The multiple reflected signals (“multipath signals”, or “multipath”) comprise the remaining response as illustrated.

FIGS. 5C, 5D, and SE represent the received signal from a TM-UWB transmitter in three different multipath environments. These figures are not actual signal plots, but are hand drawn plots approximating typical signal plots. FIG. 5C illustrates the received signal in a very low multipath environment. This may occur in a building where the receiver antenna is in the middle of a room and is one meter from the transmitter. This may also represent signals received from some distance, such as 100 meters, in an open field where there are no objects to produce reflections. In this situation, the predominant pulse is the first received pulse and the multipath reflections are too weak to be significant. FIG. 5D illustrates an intermediate multipath environment. This approximates the response from one room to the next in a building. The amplitude of the direct path signal is less than in FIG. 5C and several reflected signals are of significant amplitude. FIG. 5E approximates the response in a severe multipath environment such as: propagation through many rooms; from corner to corner in a building; within a metal cargo hold of a ship; within a metal truck trailer; or within an intermodal shipping container. In this scenario, the main path signal is weaker than in FIG. 5D. In this situation, the direct path signal power is small relative to the total signal power from the reflections.

An impulse radio receiver can receive the signal and demodulate the information using either the direct path signal or any multipath signal peak having sufficient signal to noise ratio. Thus, the impulse radio receiver can select the strongest response from among the many arriving signals. In order for the signals to cancel and produce a null at a given location, dozens of reflections would have to be cancelled simultaneously and precisely while blocking the direct path—a highly unlikely scenario. This time separation of multipath signals together with time resolution and selection by the receiver permit a type of time diversity that virtually eliminates cancellation of the signal. In a multiple correlator rake receiver, performance is further improved by collecting the signal power from multiple signal peaks for additional signal to noise performance.

Where the system of FIG. 5A is a narrow band system and the delays are small relative to the data bit time, the received signal is a sum of a large number of sine waves of random amplitude and phase. In the idealized limit, the resulting envelope amplitude has been shown to follow a Rayleigh probability distribution as follows:

$$p ( r ) = \frac{1}{{σ}^{2}} exp ( \frac{- {r}^{2}}{2 {σ}^{2}} )$$

where r is the envelope amplitude of the combined multipath signals, and 2σ² is the RMS power of the combined multipath signals.

This distribution is shown in FIG. 5F. It can be seen in FIG. 5F that 10% of the time, the signal is more than 16 dB attenuated. This suggests that 16 dB fade margin is needed to provide 90% link availability. Values of fade margin from 10 to 40 dB have been suggested for various narrow band systems, depending on the required reliability. This characteristic has been the subject of much research and can be partially improved by such techniques as antenna and frequency diversity, but these techniques result in additional complexity and cost.

In a high multipath environment such as inside homes, offices, warehouses, automobiles, trailers, shipping containers, or outside in the urban canyon or other situations where the propagation is such that the received signal is primarily scattered energy, impulse radio, according to the present invention, can avoid the Rayleigh fading mechanism that limits performance of narrow band systems. This is illustrated in FIG. 5G and 5H in a transmit and receive system in a high multipath environment 5G00, wherein the transmitter 5G06 transmits to receiver 5G08 with the signals reflecting off reflectors 5G03 which form multipaths 5G02. The direct path is illustrated as 5G01 with the signal graphically illustrated at 5H02, with the vertical axis being the signal strength in volts and horizontal axis representing time in nanoseconds. Multipath signals are graphically illustrated at 5H04.

Distance Measurement

Important for positioning, impulse systems can measure distances to extremely fine resolution because of the absence of ambiguous cycles in the waveform. Narrow band systems, on the other hand, are limited to the modulation envelope and cannot easily distinguish precisely which RF cycle is associated with each data bit because the cycle-to-cycle amplitude differences are so small they are masked by link or system noise. Since the impulse radio waveform has no multi-cycle ambiguity, this allows positive determination of the waveform position to less than a wavelength—potentially, down to the noise floor of the system. This time position measurement can be used to measure propagation delay to determine link distance, and once link distance is known, to transfer a time reference to an equivalently high degree of precision. The inventors of the present invention have built systems that have shown the potential for centimeter distance resolution, which is equivalent to about 30 ps of time transfer resolution. See, for example, commonly owned, co-pending applications Ser. No. 09/045,929, filed Mar. 23, 1998, titled “Ultrawide-Band Position Determination System and Method”, and Ser. No. 09/083,993, filed May 26, 1998, titled “System and Method for Distance Measurement by Inphase and Quadrature Signals in a Radio System,” both of which are incorporated herein by reference.

In addition to the methods articulated above, impulse radio technology along with Time Division Multiple Access algorithms and Time Domain packet radios can achieve geo-positioning capabilities in a radio network. This geo-positioning method allows ranging to occur within a network of radios without the necessity of a full duplex exchange among every pair of radios.

Exemplary Transceiver Implementation

Transmitter

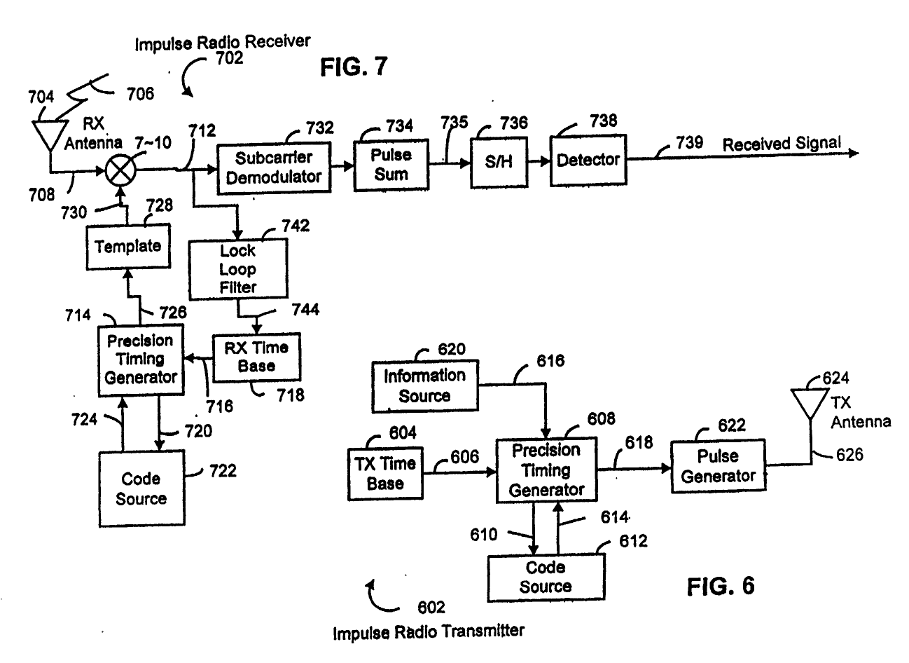

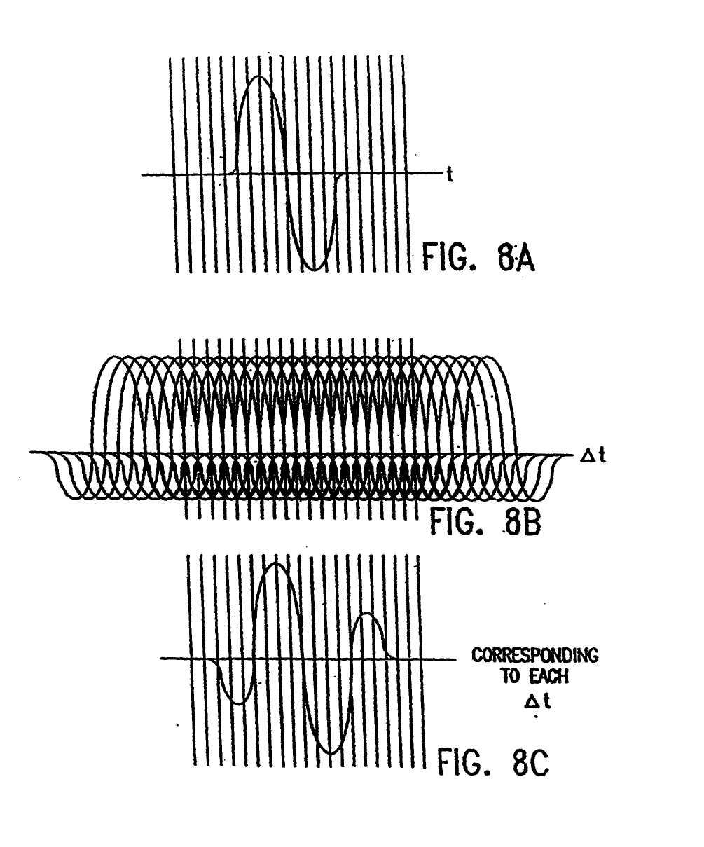

An exemplary embodiment of an impulse radio transmitter 602 of an impulse radio communication system having one subcarrier channel will now be described with reference to FIG. 6.

The transmitter 602 comprises a time base 604 that generates a periodic timing signal 606. The time base 604 typically comprises a voltage controlled oscillator (VCO), or the like, having a high timing accuracy and low jitter, on the order of picoseconds (ps). The voltage control to adjust the VCO center frequency is set at calibration to the desired center frequency used to define the transmitter's nominal pulse repetition rate. The periodic timing signal 606 is supplied to a precision timing generator 608.

The precision timing generator 608 supplies synchronizing signals 610 to the code source 612 and utilizes the code source output 614 together with an internally generated subcarrier signal (which is optional) and an information signal 616 to generate a modulated, coded timing signal 618. The code source 612 comprises a storage device such as a random access memory (RAM), read only memory (ROM), or the like, for storing suitable codes and for outputting the PN codes as a code signal 614. Alternatively, maximum length shift registers or other computational means can be used to generate the codes.

An information source 620 supplies the information signal 616 to the precision timing generator 608. The information signal 616 can be any type of intelligence, including digital bits representing voice, data, imagery, or the like, analog signals, or complex signals.

A pulse generator 622 uses the modulated, coded timing signal 618 as a trigger to generate output pulses. The output pulses are sent to a transmit antenna 624 via a transmission line 626 coupled thereto. The output pulses are converted into propagating electromagnetic pulses by the transmit antenna 624. In the present embodiment, the electromagnetic pulses are called the emitted signal, and propagate to an impulse radio receiver 702, such as shown in FIG. 7, through a propagation medium, such as air, in a radio frequency embodiment. In a preferred embodiment, the emitted signal is wide-band or ultrawide-band, approaching a monocycle pulse as in FIG. 1A. However, the emitted signal can be spectrally modified by filtering of the pulses. This bandpass filtering will cause each monocycle pulse to have more zero crossings (more cycles) in the time domain. In this case, the impulse radio receiver can use a similar waveform as the template signal in the cross correlator for efficient conversion.

Receiver

An exemplary embodiment of an impulse radio receiver (hereinafter called the receiver) for the impulse radio communication system is now described with reference to FIG. 7.

The receiver 702 comprises a receive antenna 704 for receiving a propagated impulse radio signal 706. A received signal 708 is input to a cross correlator or sampler 710 via a receiver transmission line, coupled to the receive antenna 704, and producing a baseband output 712.

The receiver 702 also includes a precision timing generator 714, which receives a periodic timing signal 716 from a receiver time base 718. This time base 718 is adjustable and controllable in time, frequency, or phase, as required by the lock loop in order to lock on the received signal 708. The precision timing generator 714 provides synchronizing signals 720 to the code source 722 and receives a code control signal 724 from the code source 722. The precision timing generator 714 utilizes the periodic timing signal 716 and code control signal 724 to produce a coded timing signal 726. The template generator 728 is triggered by this coded timing signal 726 and produces a train of template signal pulses 730 ideally having waveforms substantially equivalent to each pulse of the received signal 708. The code for receiving a given signal is the same code utilized by the originating transmitter to generate the propagated signal. Thus, the timing of the template pulse train matches the timing of the received signal pulse train, allowing the received signal 708 to be synchronously sampled in the correlator 710. The correlator 710 ideally comprises a multiplier followed by a short-term integrator to sum the multiplier product over the pulse interval.

The output of the correlator 710 is coupled to a subcarrier demodulator 732, which demodulates the subcarrier information signal from the subcarrier. The purpose of the optional subcarrier process, when used, is to move the information signal away from DC (zero frequency) to improve immunity to low frequency noise and offsets. The output of the subcarrier demodulator is then filtered or integrated in the pulse summation stage 734. A digital system embodiment is shown in FIG. 7. In this digital system, a sample and hold 736 samples the output 735 of the pulse summation stage 734 synchronously with the completion of the summation of a digital bit or symbol. The output of sample and hold 736 is then compared with a nominal zero (or reference) signal output in a detector stage 738 to determine an output signal 739 representing the digital state of the output voltage of sample and hold 736.

The baseband signal 712 is also input to a lowpass filter 742 (also referred to as lock loop filter 742). A control loop comprising the lowpass filter 742, time base 718, precision timing generator 714, template generator 728, and correlator 710 is used to generate an error signal 744. The error signal 744 provides adjustments to the adjustable time base 718 to time position the periodic timing signal 726 in relation to the position of the received signal 708.

In a transceiver embodiment, substantial economy can be achieved by sharing part or all of several of the functions of the transmitter 602 and receiver 702. Some of these include the time base 718, precision timing generator 714, code source 722, antenna 704, and the like.

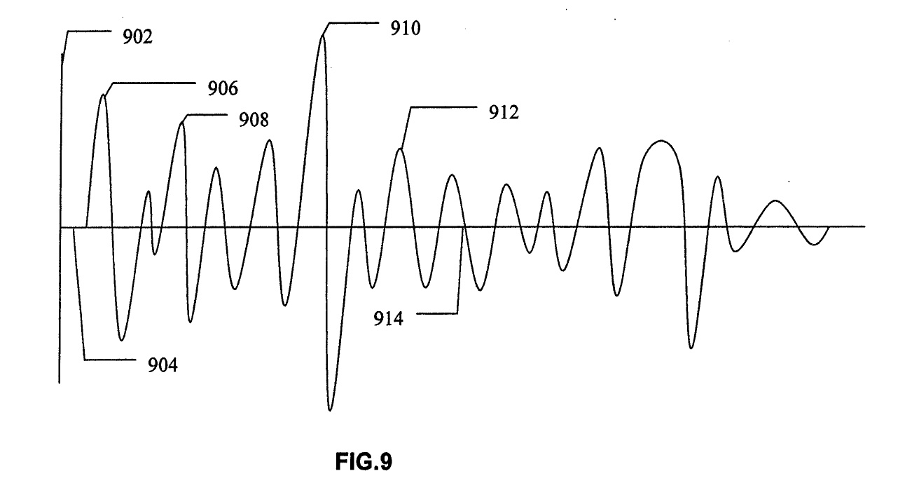

FIGS. 8A-8C illustrate the cross correlation process and the correlation function. FIG. 8A shows the waveform of a template signal. FIG. 8B shows the waveform of a received impulse radio signal at a set of several possible time offsets. FIG. 8C represents the output of the correlator (multiplier and short time integrator) for each of the time offsets of FIG. 8B. Thus, this graph does not show a waveform that is a function of time, but rather a function of time-offset. For any given pulse received, there is only one corresponding point that is applicable on this graph. This is the point corresponding to the time offset of the template signal used to receive that pulse. Further examples and details of precision timing can be found described in U.S. Pat. Ser. No. 5,677,927 and commonly owned co-pending application Ser. No. 09/146,524, filed Sep. 3, 1998, entitled “Precision Timing Generator System and Method,” both of which are incorporated herein by reference.

Recent Advances in Impulse Radio Communication

Modulation Techniques

To improve the placement and modulation of pulses and to find new and improved ways that those pulses transmit information, various modulation techniques have been developed. The modulation techniques articulated above as well as the recent modulation techniques invented and summarized below are incorporated herein by reference.

Flip Modulation

An impulse radio communications system can employ FLIP modulation techniques to transmit and receive flip modulated impulse radio signals. Further, it can transmit and receive flip with shift modulated (also referred to as quadrature flip time modulated (QFTM)) impulse radio signals. Thus, FLIP modulation techniques can be used to create two, four, or more different data states.

Flip modulators include an impulse radio receiver with a time base, a precision timing generator, a template generator, a delay, first and second correlators, a data detector and a time base adjustor. The time base produces a periodic timing signal that is used by the precision timing generator to produce a timing trigger signal. The template generator uses the timing trigger signal to produce a template signal. A delay receives the template signal and outputs a delayed template signal. When an impulse radio signal is received, the first correlator correlates the received impulse radio signal with the template signal to produce a first correlator output signal, and the second correlator correlates the received impulse radio signal with the delayed template signal to produce a second correlator output signal. The data detector produces a data signal based on at least the first correlator output signal. The time base adjustor produces a time base adjustment signal based on at least the second correlator output signal. The time base adjustment signal is used to synchronize the time base with the received impulse radio signal.

For greater elaboration of FLIP modulation techniques, the reader is directed to the patent application entitled “Apparatus, System and Method for FLIP Modulation in an Impulse Radio Communication System,” Ser. No. 09/537,692, filed Mar. 29, 2000, and assigned to the assignee of the present invention. This patent application is incorporated herein by reference.

Vector Modulation

Vector Modulation is a modulation technique which includes the steps of generating and transmitting a series of time-modulated pulses, each pulse delayed by one of four pre-determined time delay periods and representative of at least two data bits of information, and receiving and demodulating the series of time-modulated pulses to estimate the data bits associated with each pulse. The apparatus includes an impulse radio transmitter and an impulse radio receiver.

The transmitter transmits the series of time-modulated pulses and includes a transmitter time base, a time delay modulator, a code time modulator, an output stage, and a transmitting antenna. The receiver receives and demodulates the series of time-modulated pulses using a receiver time base and two correlators, one correlator designed to operate after a pre-determined delay with respect to the other correlator. Each correlator includes an integrator and a comparator, and may also include an averaging circuit that calculates an average output for each correlator, as well as a track and hold circuit for holding the output of the integrators. The receiver further includes an adjustable time delay circuit that may be used to adjust the pre-determined delay between the correlators in order to improve detection of the series of time-modulated pulses.

For greater elaboration of Vector modulation techniques, the reader is directed to the patent application entitled, “Vector Modulation System and Method for Wideband Impulse Radio Communications,” Ser. No. 09/169,765, filed Dec. 9, 1999, and assigned to the assignee of the present invention. This patent application is incorporated herein by reference.

Receivers

Because of the unique nature of impulse radio receivers, several modifications have been recently made to enhance system capabilities.

Multiple Correlator Receivers

Multiple correlator receivers utilize multiple correlators that precisely measure the impulse response of a channel and wherein measurements can extend to the maximum communications range of a system, thus, not only capturing ultra-wideband propagation waveforms, but also information on data symbol statistics. Further, multiple correlators enable rake acquisition of pulses and thus faster acquisition, tracking implementations to maintain lock and enable various modulation schemes. Once a tracking correlator is synchronized and locked to an incoming signal, the scanning correlator can sample the received waveform at precise time delays relative to the tracking point. By successively increasing the time delay while sampling the waveform, a complete, time-calibrated picture of the waveform can be collected.

For greater elaboration of utilizing multiple correlator techniques, the reader is directed to the patent application entitled, “System and Method of using Multiple Correlator Receivers in an Impulse Radio System” Ser. No. 09/537,264, filed Mar. 29, 2000, and assigned to the assignee of the present invention. This patent application is incorporated herein by reference.

Fast Locking Mechanisms

Methods to improve the speed at which a receiver can acquire and lock onto an incoming impulse radio signal have been developed. In one approach, a receiver comprises an adjustable time base to output a sliding periodic timing signal having an adjustable repetition rate and a decode timing modulator to output a decode signal in response to the periodic timing signal. The impulse radio signal is cross-correlated with the decode signal to output a baseband signal. The receiver integrates T samples of the baseband signal and a threshold detector uses the integration results to detect channel coincidence. A receiver controller stops sliding the time base when channel coincidence is detected. A counter and extra count logic, coupled to the controller, are configured to increment or decrement the address counter by one or more extra counts after each T pulses is reached in order to shift the code modulo for proper phase alignment of the periodic timing signal and the received impulse radio signal. This method is described in detail in U.S. Pat. No. 5,832,035 to Fullerton, incorporated herein by reference.

In another approach, a receiver obtains a template pulse train and a received impulse radio signal. The receiver compares the template pulse train and the received impulse radio signal to obtain a comparison result. The system performs a threshold check on the comparison result. If the comparison result passes the threshold check, the system locks on the received impulse radio signal. The system may also perform a quick check, a synchronization check, and/or a command check of the impulse radio signal. For greater elaboration of this approach, the reader is directed to the patent application entitled, “Method and System for Fast Acquisition of Ultra Wideband Signals,” Ser. No. 09/538,292, filed Mar. 29, 2000, and assigned to the assignee of the present invention. This patent application is incorporated herein by reference.

Baseband Signal Converters

A receiver has been developed which includes a baseband signal converter device and combines multiple converter circuits and an RF amplifier in a single integrated circuit package. Each converter circuit includes an integrator circuit that integrates a portion of each RF pulse during a sampling period triggered by a timing pulse generator. The integrator capacitor is isolated by a pair of Schottky diodes connected to a pair of load resistors. A current equalizer circuit equalizes the current flowing through the load resistors when the integrator is not sampling. Current steering logic transfers load current between the diodes and a constant bias circuit depending on whether a sampling pulse is present.

For greater elaboration of utilizing baseband signal converters, the reader is directed to the patent application entitled, “Baseband Signal Converter for a Wideband Impulse Radio Receiver,” Ser. No. 09/356,384, filed Jul. 16, 1999, and assigned to the assignee of the present invention. This patent application is incorporated herein by reference.

Power Control and Interference

Power Control

Power control improvements have been invented with respect to impulse radios. The power control systems comprise a first transceiver that transmits an impulse radio signal to a second transceiver. A power control update is calculated according to a performance measurement of the signal received at the second transceiver. The transmitter power of either transceiver, depending on the particular embodiment, is adjusted according to the power control update. Various performance measurements are employed according to the current invention to calculate a power control update, including bit error rate, signal-to-noise ratio, and received signal strength, used alone or in combination. Interference is thereby reduced, which is particularly important where multiple impulse radios are operating in close proximity and their transmissions interfere with one another. Reducing the transmitter power of each radio to a level that produces satisfactory reception increases the total number of radios that can operate in an area without saturation. Reducing transmitter power also increases transceiver efficiency.

For greater elaboration of utilizing baseband signal converters, the reader is directed to the patent application entitled, “System and Method for Impulse Radio Power Control,” Ser. No. 09/332,501, filed Jun. 14, 1999, and assigned to the assignee of the present invention. This patent application is incorporated herein by reference.

Mitigating Effects of Interference

To assist in mitigating interference to impulse radio systems a methodology has been invented. The method comprises the steps of: (a) conveying the message in packets; (b) repeating conveyance of selected packets to make up a repeat package; and (c) conveying the repeat package a plurality of times at a repeat period greater than twice the occurrence period of the interference. The communication may convey a message from a proximate transmitter to a distal receiver, and receive a message by a proximate receiver from a distal transmitter. In such a system, the method comprises the steps of: (a) providing interference indications by the distal receiver to the proximate transmitter; (b) using the interference indications to determine predicted noise periods; and (c) operating the proximate transmitter to convey the message according to of the following: (1) avoiding conveying the message during noise periods; (2) conveying the message at a higher power during noise periods; (3) increasing error detection coding in the message during noise periods; (4) re-transmitting the message following noise periods; (5) avoiding conveying the message when interference is greater than a first strength; (6) conveying the message at a higher power when the interference is greater than a second strength; (7) increasing error detection coding in the message when the interference is greater than a third strength; and (8) re-transmitting a portion of the message after interference has subsided to less than a predetermined strength.

For greater elaboration of mitigating interference to impulse radio systems, the reader is directed to the patent application entitled, “Method for Mitigating Effects of Interference in Impulse Radio Communication,” Ser. No. 09/587,033, filed Jun. 2, 1999, and assigned to the assignee of the present invention. This patent application is incorporated herein by reference.

Moderating Interference while Controlling Equipment

Yet another improvement to impulse radio includes moderating interference with impulse radio wireless control of an appliance; the control is affected by a controller remote from the appliance transmitting impulse radio digital control signals to the appliance. The control signals have a transmission power and a data rate. The method comprises the steps of (a) in no particular order: (1) establishing a maximum acceptable noise value for a parameter relating to interfering signals; (2) establishing a frequency range for measuring the interfering signals; (b) measuring the parameter for the interference signals within the frequency range; and (c) when the parameter exceeds the maximum acceptable noise value, effecting an alteration of transmission of the control signals.

For greater elaboration of moderating interference while effecting impulse radio wireless control of equipment, the reader is directed to the patent application entitled, “Method and Apparatus for Moderating Interference While Effecting Impulse Radio Wireless Control of Equipment,” Ser. No. 09/586,163, filed Jun. 2, 1999, and assigned to the assignee of the present invention. This patent application is incorporated herein by reference.

Coding Advances

The improvements made in coding can directly improve the characteristics of impulse radio as used in the present invention. Specialized coding techniques may be employed to establish temporal and/or non-temporal pulse characteristics such that a pulse train will possess desirable properties. Coding methods for specifying temporal and non-temporal pulse characteristics are described in commonly owned, co-pending applications entitled “A Method and Apparatus for Positioning Pulses in Time,” Ser. No. 09/592,249, and “A Method for Specifying Non-Temporal Pulse Characteristics,” Ser. No. 09/592,250, both filed Jun. 12, 2000, and both of which are incorporated herein by reference. Essentially, a temporal or non-temporal pulse characteristic value layout is defined, an approach for mapping a code to the layout is specified, a code is generated using a numerical code generation technique, and the code is mapped to the defined layout per the specified mapping approach.

A temporal or non-temporal pulse characteristic value layout may be fixed or non-fixed and may involve value ranges, discrete values, or a combination of value ranges and discrete values. A value range layout specifies a range of values for a pulse characteristic that is divided into components that are each subdivided into subcomponents, which can be further subdivided, ad infinitum. In contrast, a discrete value layout involves uniformly or non-uniformly distributed discrete pulse characteristic values. A non-fixed layout (also referred to as a delta layout) involves delta values relative to some reference value such as the characteristic value of the preceding pulse. Fixed and non-fixed layouts, and approaches for mapping code element values to them, are described in co-owned, co-pending applications, entitled “Method for Specifying Pulse Characteristics using Codes,” Ser. No. 09/592,290, and “A Method and Apparatus for Mapping Pulses to a Non-Fixed Layout,” Ser. No. 09/591,691, both filed on Jun. 12, 2000, and both of which are incorporated herein by reference.

A fixed or non-fixed characteristic value layout may include one or more non-allowable regions within which a characteristic value of a pulse is not allowed. A method for specifying non-allowable regions to prevent code elements from mapping to non-allowed characteristic values is described in co-owned, co-pending application entitled “A Method for Specifying Non-Allowable Pulse Characteristics,” Ser. No. 09/592,289, filed Jun. 12, 2000, and incorporated herein by reference. A related method that conditionally positions pulses depending on whether or not code elements map to non-allowable regions is described in co-owned, co-pending application, entitled “A Method and Apparatus for Positioning Pulses Using a Layout having Non-Allowable Regions,” Ser. No. 09/592,248, and incorporated herein by reference.

Typically, a code consists of a number of code elements having integer or floating-point values. A code element value may specify a single pulse characteristic (e.g., pulse position in time) or may be subdivided into multiple components, each specifying a different pulse characteristic. For example, a code having seven code elements each subdivided into five components (c0-c4) could specify five different characteristics of seven pulses. A method for subdividing code elements into components is described in commonly owned, co-pending application entitled “Method for Specifying Pulse Characteristics using Codes,” Ser. No. 09/592,290, filed Jun. 12, 2000, previously referenced and again incorporated herein by reference. Essentially, the value of each code element or code element component (if subdivided) maps to a value range or discrete value within the defined characteristic value layout. If a value range layout is used an offset value is typically employed to specify an exact value within the value range mapped to by the code element or code element component.

The signal of a coded pulse train can be generally expressed:

$${s}_{tr}^{( k )} ( t ) = {\sum }_{j} {( - 1 )}^{{f}_{j}^{( k )}} {a}_{j}^{( k )} ω ( {c}_{j}^{( k )} t - {T}_{j}^{( k )} , {b}_{j}^{( k )} )$$

where k is the index of a transmitter, j is the index of a pulse within its pulse train, (−1)fⱼ^{(k)}, aⱼ^{(k)}, cⱼ^{(k)}, and bⱼ^{(k)} are the coded polarity, amplitude, width, and waveform of the jth pulse of the kth transmitter, and Tⱼ^{(k)} is the coded time shift of the jth pulse of the kth transmitter. Note: When a given non-temporal characteristic does not vary (i.e., remains constant for all pulses in the pulse train), the corresponding code element component is removed from the above expression and the non-temporal characteristic value becomes a constant in front of the summation sign.

Various numerical code generation methods can be employed to produce codes having certain correlation and spectral properties. Such codes typically fall into one of two categories: designed codes and pseudorandom codes.

A designed code may be generated using a quadratic congruential, hyperbolic congruential, linear congruential, Costas array or other such numerical code generation technique designed to generate codes guaranteed to have certain correlation properties. Each of these alternative code generation techniques has certain characteristics to be considered in relation to the application of the pulse transmission system employing the code. For example, Costas codes have nearly ideal autocorrelation properties but somewhat less than ideal cross-correlation properties, while linear congruential codes have nearly ideal cross-correlation properties but less than ideal autocorrelation properties. In some cases, design tradeoffs may require that a compromise between two or more code generation techniques be made such that a code is generated using a combination of two or more techniques. An example of such a compromise is an extended quadratic congruential code generation approach that uses two ‘independent’ operators, where the first operator is linear and the second operator is quadratic. Accordingly, one, two, or more code generation techniques or combinations of such techniques can be employed to generate a code without departing from the scope of the invention.

A pseudorandom code may be generated using a computer's random number generator, binary shift-register(s) mapped to binary words, a chaotic code generation scheme, or another well-known technique. Such ‘random-like’ codes are attractive for certain applications since they tend to spread spectral energy over multiple frequencies while having ‘good enough’ correlation properties, whereas designed codes may have superior correlation properties but have spectral properties that may not be as suitable for a given application.

Computer random number generator functions commonly employ the linear congruential generation (LCG) method or the Additive Lagged-Fibonacci Generator (ALFG) method. Alternative methods include inversive congruential generators, explicit-inversive congruential generators, multiple recursive generators, combined LCGs, chaotic code generators, and Optimal Golomb Ruler (OGR) code generators. Any of these or other similar methods can be used to generate a pseudorandom code without departing from the scope of the invention, as will be apparent to those skilled in the relevant art.

Detailed descriptions of code generation and mapping techniques are included in a co-owned patent application entitled “A Method and Apparatus for Positioning Pulses in Time,” Attorney Docket #: 28549-165554, which is hereby incorporated by reference.

It may be necessary to apply predefined criteria to determine whether a generated code, code family, or a subset of a code is acceptable for use with a given UWB application. Criteria to consider may include correlation properties, spectral properties, code length, non-allowable regions, number of code family members, or other pulse characteristics. A method for applying predefined criteria to codes is described in co-owned, co-pending application, entitled “A Method and Apparatus for Specifying Pulse Characteristics using a Code that Satisfies Predefined Criteria,” Ser. No. 09/592,288, filed Jun. 12, 2000, and is incorporated herein by reference.

In some applications, it may be desirable to employ a combination of two or more codes. Codes may be combined sequentially, nested, or sequentially nested, and code combinations may be repeated. Sequential code combinations typically involve transitioning from one code to the next after the occurrence of some event. For example, a code with properties beneficial to signal acquisition might be employed until a signal is acquired, at which time a different code with more ideal channelization properties might be used. Sequential code combinations may also be used to support multicast communications. Nested code combinations may be employed to produce pulse trains having desirable correlation and spectral properties. For example, a designed code may be used to specify value range components within a layout and a nested pseudorandom code may be used to randomly position pulses within the value range components. With this approach, correlation properties of the designed code are maintained since the pulse positions specified by the nested code reside within the value range components specified by the designed code, while the random positioning of the pulses within the components results in desirable spectral properties. A method for applying code combinations is described in co-owned, co-pending application, entitled “A Method and Apparatus for Applying Codes Having Pre-Defined Properties,” Ser. No. 09/591,690, filed Jun. 12, 2000, which is incorporated herein by reference.

Positioning Impulses for Advantageous Operation in the Presence of Multipath

The present invention relates to the placing of pulses in advantageous time positions relative to the local multipath to enhance reception of data modulated on the impulse signal. As noted previously, impulse signals may be modulated in time or amplitude or pulse shape or by varying any signal characteristic; however, for illustration purposes amplitude modulation or more particularly polarity modulation where the amplitude values are +1 or −1 is used in this document. Other types of modulation may be used and may be extrapolated from the principles disclosed herein.

FIG. 9 is an illustration depicting a typical received impulse signal voltage 902 vs. time 904 plot including both the direct path 906 and the multipath components. Several peak responses 906, 908, 910, 912 are indicated where a receiving correlator may be placed in time to receive signal energy. In addition, a zero crossing, or null position 914 is identified. Note also that peak 908 is larger than the direct signal 906. This is not uncommon since any given multipath response peak may be the sum of several reflections, whereas, the direct path can only be one.

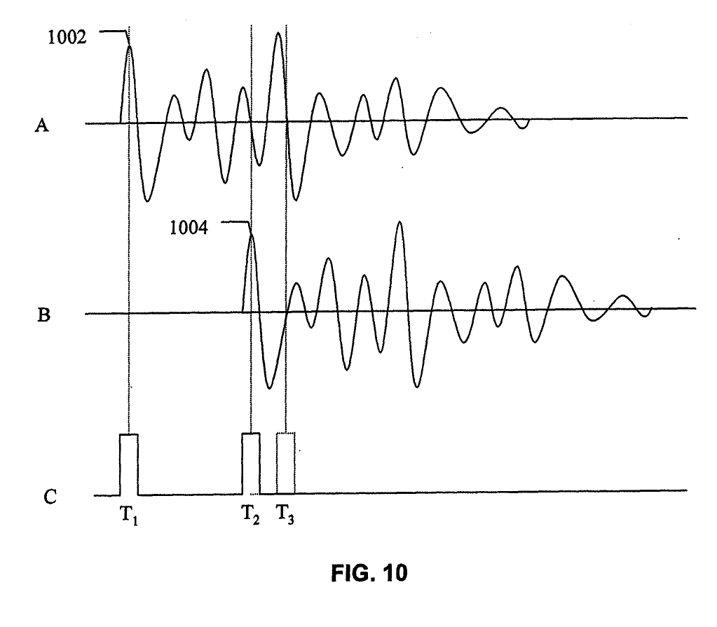

FIG. 10 illustrates an exemplary system wherein two pulses 1002, 1004 are to be sent in rapid succession in accordance with the present invention. Each pulse may have independent modulation. That is, each pulse may be sent in the polarity shown or may be inverted in accordance with the information being sent.

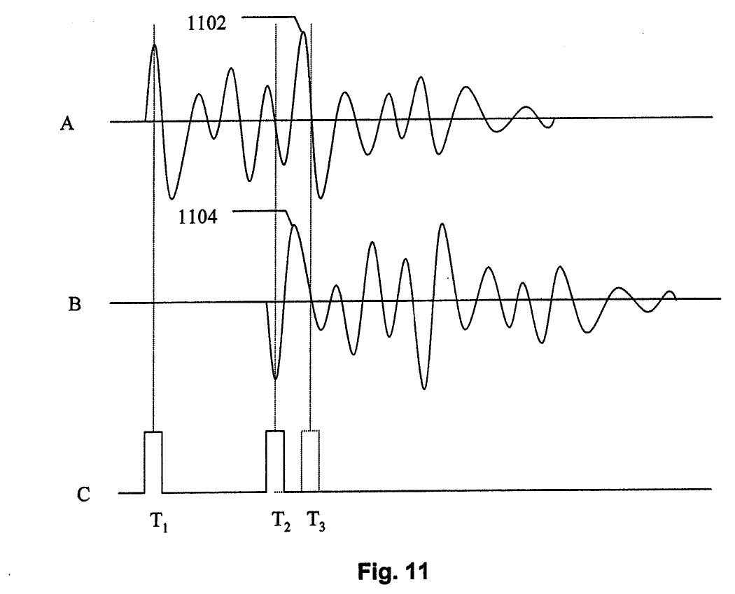

FIG. 11 illustrates the placement of two pulses such that the second pulse 1104 is coincident with a zero crossing of the response to the first pulse 1102. In this figure, responses A and B are shown in separate plots. In practice, the received signal is the sum of these two signals and each individual signal does not separately exist, however, they are shown separate here for the purpose of explanation. Plot B of FIG. 11 is identical in shape to plot A, but is delayed in time because it is the result of a delayed transmitted pulse. The actual received signal (not shown) is the sum of these two signals. Plot C represents receiver sampling pulses timed to be coincident with the received pulse response.

As can be seen from these illustrations, when a second pulse is timed at an arbitrary location in the midst of the first pulse multipath response, the first pulse may add or subtract a signal of unknown amplitude which may severely reduce the noise margin of the second pulse reception, and may in fact exceed the second pulse signal level. It is this situation that forces typical impulse radio designers to use pulse to pulse times greater than the multipath decay time so that the second pulse occurs after sufficient decay of the multipath energy so that it does not impact system margins.

Alternatively, integration gain may be used to overcome multipath interference, but this also reduces the system data rate. One of the features of the present invention is to overcome multipath interference while allowing high pulse rates that enable high data rates. Such a method is illustrated in FIG. 11. In this figure the first pulse is received at time T₁ and a correlator sample is taken coincident with this signal. The second pulse is sent at time T₂ and a correlator sample is taken coincident with this time also. As shown in the figure, time T₂ is carefully chosen such that it is coincident with a zero crossing of waveform A. Thus Pulse A may be either positive or negative in polarity with no effect in the signal sampling at time position T₂, which is the B signal sample, thereby allowing high pulse rate signals in the presence of multipath.

Note also in FIG. 11 that an alternative second pulse location is identified as location T₃. This location also aligns with a zero crossing on waveform A, but is the zero crossing of a larger response. In an ideal system, this would be equivalent to the location T₂, but in practical systems, timing jitter will prevent precise alignment and will result in a noise that will reduce system margins, thus, it is preferable to find zero crossings associated with low responses or otherwise with a low slope.

In a preferred embodiment of the invention, the second pulse is timed to occur in coincidence with a maximum of the multipath response. This, however, requires additional processing to efficiently demodulate each of the pulse signals with their independent modulation states.

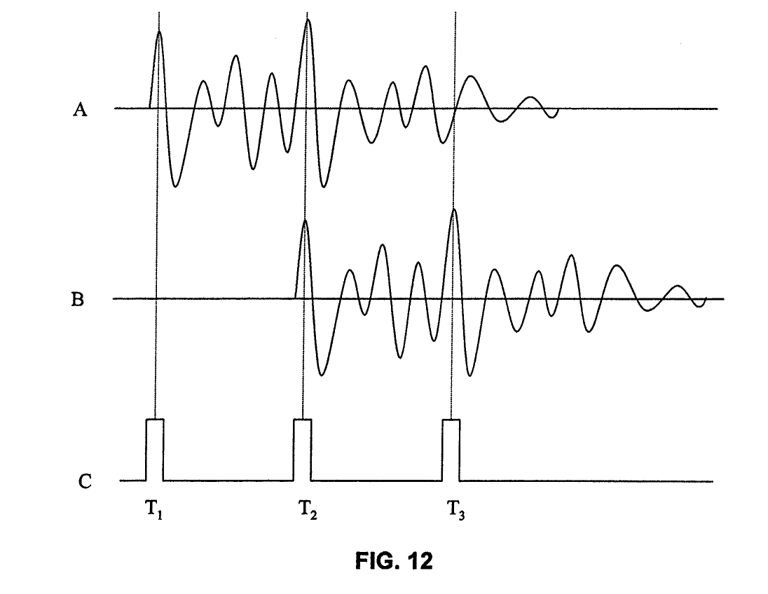

FIG. 12 illustrates this timing relationship. Again plot A represents the received signal from the first pulse. Plot B represents the received signal from the second pulse, and plot C represents the sampling pulse timing relative to the received signals.

In FIG. 12, the sample at T₁ is coincident with the direct response of the first pulse. The sample at T₂ is coincident with the direct response of the second pulse and is also coincident with a maximum response of the multipath resulting from the first pulse. The actual sample would be the sum of these two signal values. The same at T₃ is coincident with the corresponding maximum response due to the second pulse. Coincidentally, this sample is also aligned with a zero crossing of the multipath response due to the first pulse. This is ideal, but is difficult to control in a typical situation. In the average case, this would line up off peak on a lesser response point, the higher responses being selected for controlled line-up.

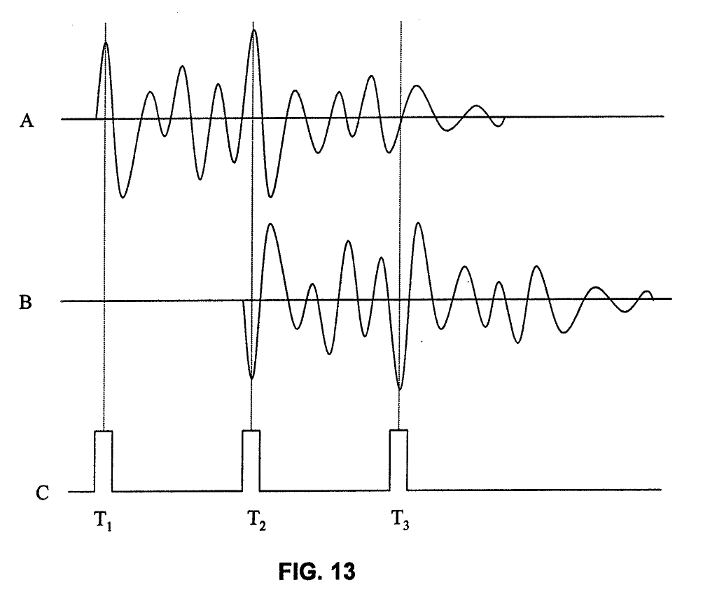

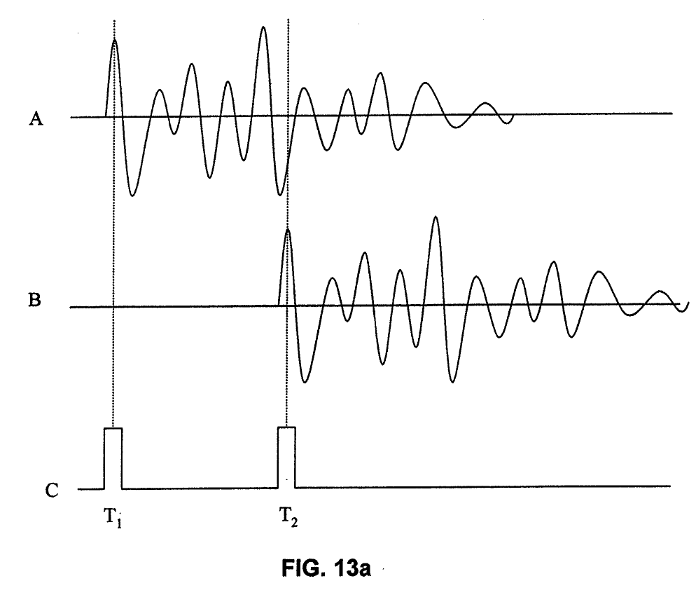

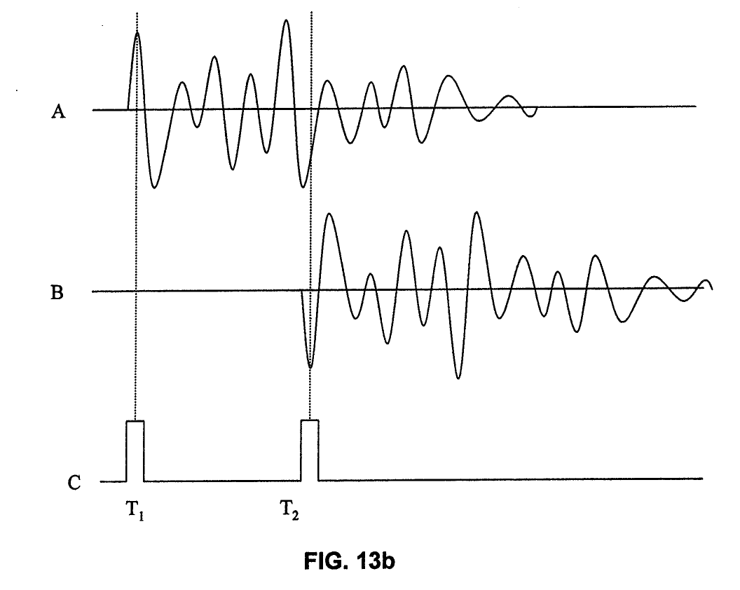

Note that in the case of the T₂ sample time, there is a major ambiguity with respect to the possible modulation. Either signal A or signal B may be flipped in sign as shown in FIG. 13 (where B is flipped). Shown in FIG. 13a and FIG. 13b is the signal flipped and time offset. Where these two signals are near equal, as shown, the resulting sum may be positive double, near zero, or negative double, depending on the modulation.

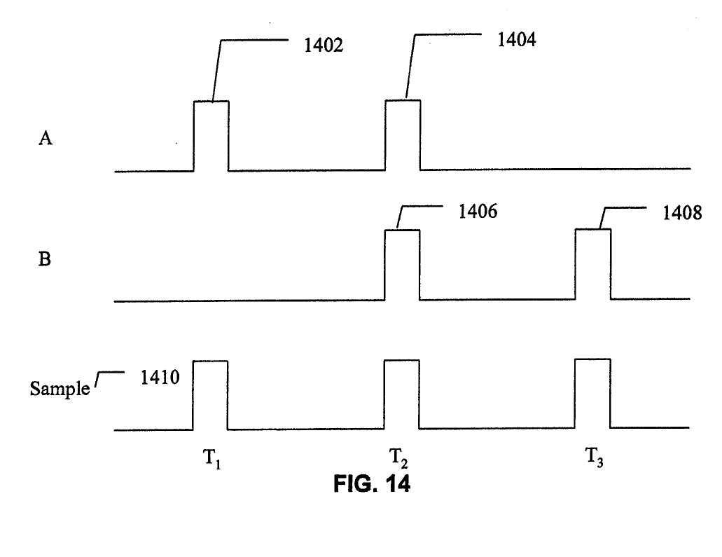

FIG. 14 is a simplified version of FIG. 12 for illustration of how these ambiguities can be resolved with a resulting improvement in signal to noise over a simple flip modulation case. In this figure, A is the first pulse direct response 1402 with its major multipath response 1404. B is the second pulse direct response 1406 with its major multipath response 1408. C is the sample timing 1410. For simplicity all pulses have the same amplitude of V=1.

Table 1 tabulates the correlator signal voltages for the four possible modulation states (i.e. each state positive or negative-cases w,x,y,z). It can be seen that when all three correlator outputs are taken together, there is no modulation ambiguity even though any one correlator has one or more duplicate values. Upon closer examination, table 2 lists the difference between any two states listed in table 1. Here we note that all states have two correlators with a distance of at least two and one correlator with a distance of zero.

TABLE 1
Correlator outputs for different modulation states

| | | Correlator | Correlator | Correlator |
|---|---|---|---|---|
| Case | Modulation | T1 | T2 | T3 |
| W | AA+, BB+ | 1 | 2 | 1 |
| X | AA+, BB− | 1 | 0 | −1 |
| Y | AA−, BB+ | −1 | 0 | 1 |
| Z | AA−, BB− | −1 | −2 | −1 |

TABLE 2
Correlator output differences among the
possible modulation states.

| | Correlator | Correlator | Correlator | |
|---|---|---|---|---|
| Difference | 1 | 2 | 3 | 3D Vector |
| W-X | 0 | 2 | 2 | 2sqrt(2) |
| W-Y | 2 | 2 | 0 | 2sqrt(2) |
| W-Z | 2 | 4 | 2 | 2sqrt(6) |
| X-Y | 2 | 0 | −2 | 2sqrt(2) |
| X-Z | 2 | 2 | 0 | 2sqrt(2) |
| Y-Z | 0 | 2 | 2 | 2sqrt(2) |

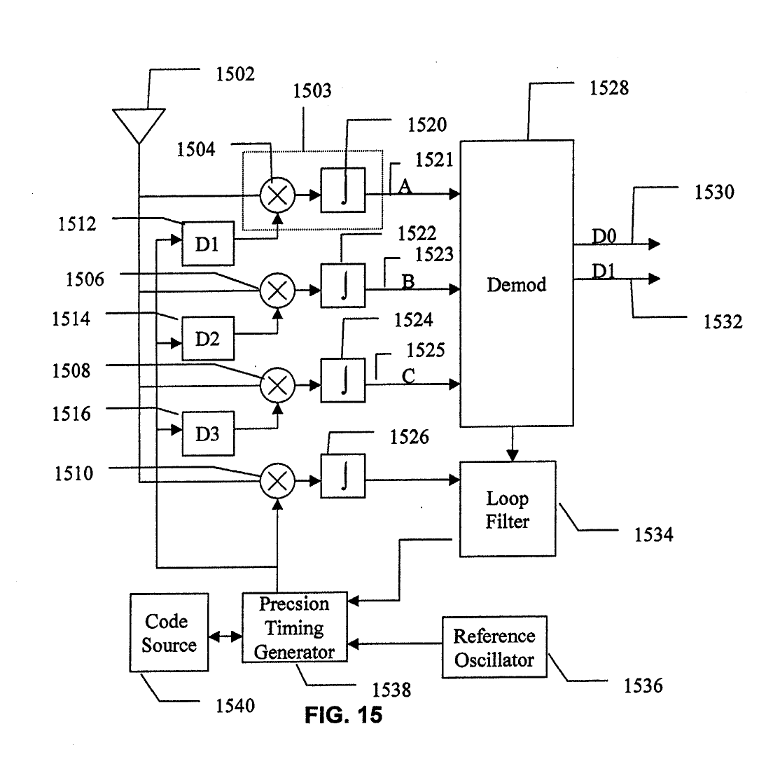

FIG. 15 is an exemplary block diagram of a receiver system in accordance with the present invention. This example illustrates three samplers in a parallel configuration in the data path and a single sampler for in the tracking loop path. It should be appreciated that one skilled in the art may extend this configuration to many samplers to handle as many sampling points as necessary. This function may also be achieved by fewer samplers, possibly a single sampler operating at a higher rate and multiplexed among the various sample times.

Returning to FIG. 15, the impulse signal is received by the antenna 1502 and coupled to four samplers. Each sampler comprising a multiply 1504 and integrate 1520 function. Three of these samplers, 1504, 1506, 1508, are positioned in time to receive signal energy for demodulation of data and integration by integrators 1520, 1522 and 1524. The outputs of these samplers are coupled to a demodulation function 1528 which determines a data output D0, 1530 and D1, 1532, based on the input signals 1521, 1523, 1525. The timing for each sampler is based on the timing established by the tracking loop comprising sampler 1510, integrate function 1526, loop filter 1534, precision timing generator 1538, reference oscillator 1536, and code source 1540. In a preferred embodiment, the tracking loop includes an input from the demodulation function to invert the polarity of the error signal based on the detected modulation state of an associated pulse.

Each sampler 1504, 1506, 1508, receives its timing from a programmable delay 1512, 1514, 1516, whose delay values correspond to the delay values used by the transmitter to transmit the pulse stream. These values may initially be default values that are later replaced by values that are based on channel response measurements.

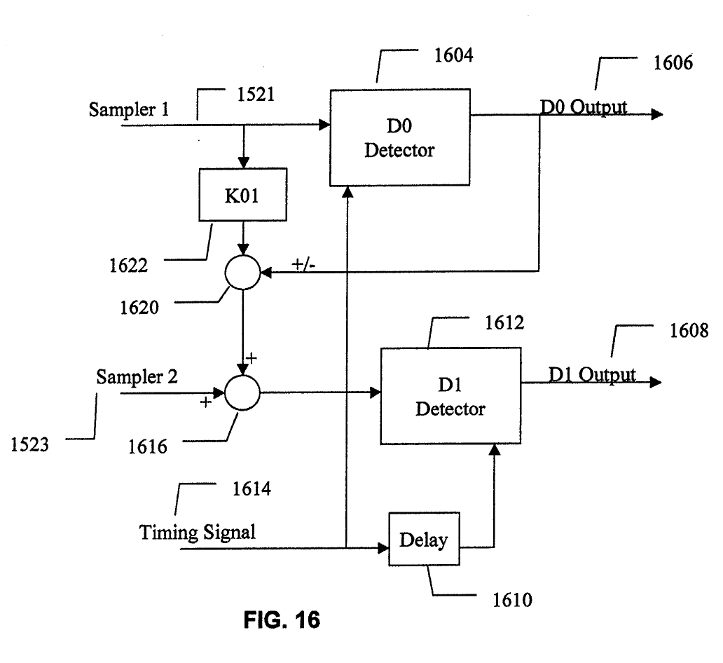

FIG. 16 is an exemplary block diagram of a feed forward demodulation function 1528 as illustrated in FIG. 15. In this figure, the first sampler, 1521 output is fed to the first data bit detector, D0 1604. In the case of flip modulation this detector may be simply a comparator which determines the polarity of the signal immediately at the end of pulse sampling according to the timing signal 1614. The data output is then fed to a multiplier that corrects the polarity of the sample and adds it to the sample from sampler 2, 1523 in order to subtract the coupling from the first pulse into the second pulse due to the channel multipath response. This combined signal is then detected by detector 1612 to yield the second data D1 output 1608. Again this detector may be simply a comparator configured to determine the polarity of the combined signal. The timing for the second detection operation is after the end of the second sampling operation.

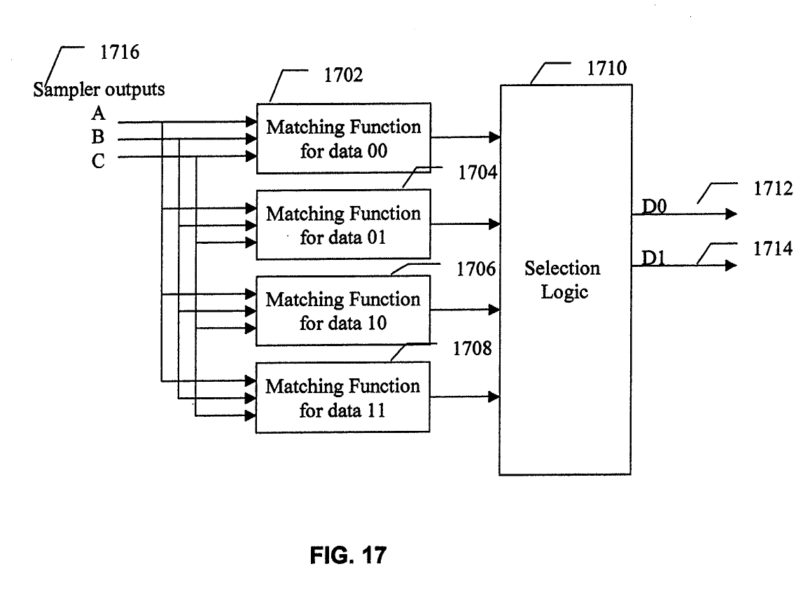

FIG. 17 is a block diagram of a parallel detection system in accordance with the present invention. In the example illustrated, two data bits are transmitted using two separate pulses, a first pulse and a second pulse. The second pulse is timed to be coincident with the maximum of a multipath response from the first pulse as shown in FIGS. 12 and 13.

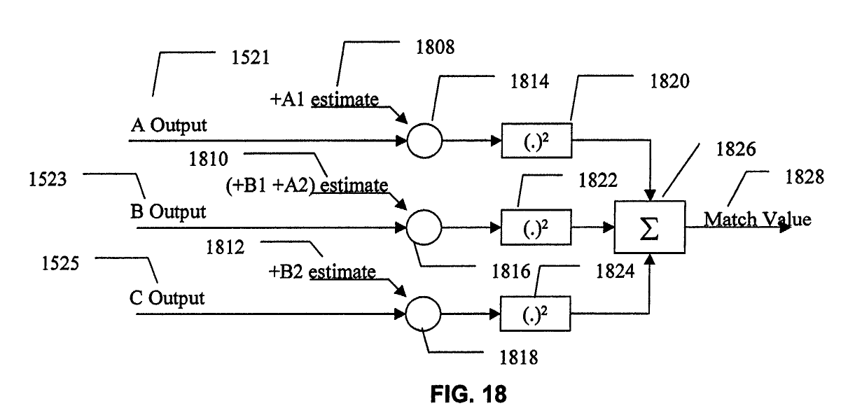

The sampler outputs 1521, 1523, 1525 are fed to four matching functions 1702, 1704, 1706 and 1708, one for each possible data bit combination, 00, 01, 10, 11. An exemplary matching function will be later discussed with reference to FIG. 18. The outputs of the matching functions are fed to the selection logic 1710. Since each matching function outputs the difference between the actual and expected signal set, the lowest value represents the most likely data based on the input signals. The selection logic 1710 performs this logic and outputs the associated data 1712, 1714.

An exemplary matching function as depicted in FIG. 17 will now be described with reference to FIG. 18. The A, B and C sampler outputs 1521, 1523 and 1525 are compared with their respective signal estimates given the respective data assumption for each matching function. In the example shown, it is assumed that a zero input to the transmitter modulator results in a positive modulation and a one input results in an inverse. Thus, for a 0,0 input the A output would be expected to be equal to the Al signal level. (The A1 signal level is the first pulse signal at the A sampler. This level is subtracted at the A comparator 1814. The result is then squared and provided to the summing function to yield a mean square error output.

Likewise, the B sampler output 1523 is compared with its expected value 1812. This value 1810 is the first response from the second pulse plus the second response from the first pulse. This value is also squared 1822 and summed 1826. And likewise, the C sampler 1525 is compared with the second response of the second pulse, the squared result 1824 summed 1826 with the rest for a final output mean square error output 1828.

In a similar manner the remaining matching functions 1704, 1706, 1708 generate their respective mean square error signals relative to their respective expected signals.

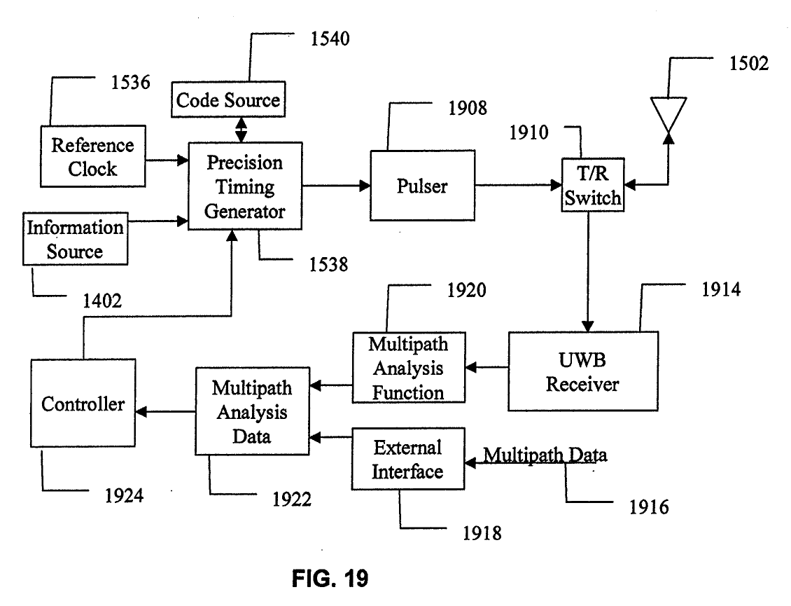

FIG. 19 represents a block diagram of a transceiver system in accordance with the present invention. This transceiver comprises a transmitter side and a receiver side. The transmitter side comprises a precision timing generator 1538 to generate the timing for positioning pulses in accordance with the present invention. The timing generator 1538 receives signal inputs to be transmitted from an information source 1402. These signals are used to modulate the signal according to the chosen modulation format. In the modulation format for present example, the information source 1402 is digital and the zero state is used to invert a pulse whereas the one state sends a pulse in true polarity.

The timing generator 1538 also receives a reference clock 1536 input to provide the source timing for the radio functions. The timing generator 1538 also interfaces with an optional code source 1540 to provide codes as necessary for the radio.

The timing generator 1538 also receives commands from a controller 1924 that provides precise timing information for placement of pulses based on measured multipath data. This timing information may be provided to the timing generator 1538 where it is added to code information, or in another embodiment, this timing information may be used to modify the code, resulting in a new code that contains the necessary information.

The output of the timing generator 1538 drives a pulser 1908 which generates and shapes the signal to be fed to the antenna 1502. In a single antenna embodiment, means is provided for transmit and receive signals to share the same antenna. FIG. 19 shows a Transmit/Receive switch 1910 for this function. The output of the TR switch 1910 is fed to the antenna 1502 and coupled to the medium.

Continuing now with the receive side of the transceiver shown in FIG. 19, a receive signal is coupled to the antenna 1502, then through the TR switch 1910 to the input of the UWB receiver 1914. This receiver may contain the functions illustrated in FIG. 15. In a transceiver, several of the functions may be shared between the transmitter and receiver functions. These include such functions as the reference clock, code source, precision timing generator, antenna, and other functions.

For the receiver constructed in accordance with embodiment of this invention, the receiver functions include a multipath analysis function 1920. The output of the multipath analysis function 1920 is a set of data indicating the relative pulse timing for operation in the measured multipath 1922. In an alternative embodiment, this data 1916 may be received from an external source such as over a network. An interface 1918 to this external source is shown in FIG. 19. The multipath analysis data 1922 is then provided to a controller 1924 that generates commands to the precision timing generator 1538 for proper pulse positioning.

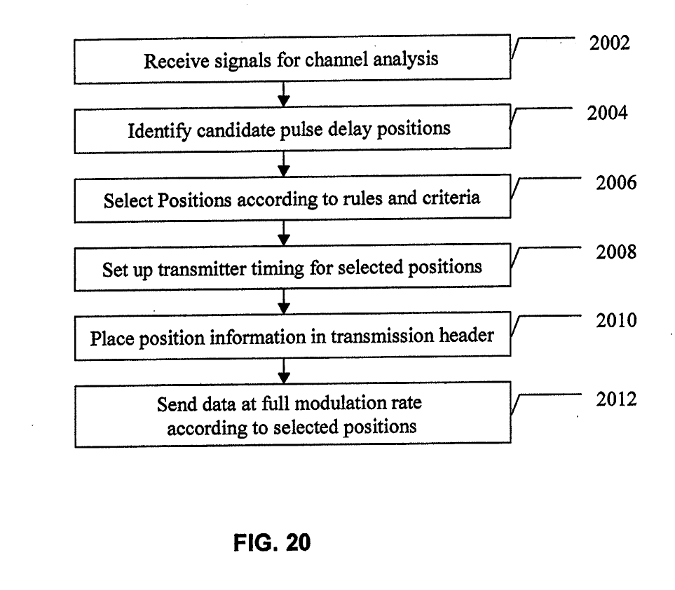

Operation of the total system will now be described with reference to FIG. 20. Initially, a system establishes operation without regard for special timing relating to the specific channel. Receipt of the signals for channel analysis occurs at 2002, whereafter the candidate pulse delay position candidates are identified at 2004. This operation will likely be at a lower data rate or higher error rate than will be achieved with the proper timing. Once a basic link is established, a receiver scans the multipath while maintaining lock on the basic signal. This multipath trace is then analyzed for zero crossing times or relative maximum response times and amplitudes as necessary for the algorithm chosen. The positions are thus selected according to rules and criteria in 2006. The timing positions are then determined and the transmitter is set up to begin the new timing at 2008. This position information is placed in the transmission header at 2010 and the data is sent at full modulation rate according to selected positions at 2012. The analysis calculations may be performed at either the transmitter or receiver site. In a preferred embodiment, synchronization information is sent from the transmitter to indicate a time of switch over to the new timing sequence. At the appointed frame number, both the transmitter and receiver change to the new sequence simultaneously so that no data is lost. At the time of switch over accommodation should be made for track loop settling time on the new parameters. Once operation is established using the new parameters, signal to noise and bit error rate may be verified.

In a further embodiment of the invention, once operation is established, each critical timing parameter is subject to a tracking loop to fine tune the initial values and to track changes due to mobility of the transceiver or changes in the environment such as mobility of a multipath reflector source.

What is claimed is:

1. A method for determining a pulse characteristic of a transmitted pulse, comprising the steps of
a. transmitting a first pulse having a first pulse characteristic;
b. receiving said transmitted pulse having said first pulse characteristic;
c. determining multipath response characteristic of said received first pulse; and
d. determining a second pulse characteristic of a second transmitted pulse based on said multipath response characteristic.

2. The method according to claim 1, wherein a pulse characteristic of said first and second pulse characteristic corresponds to a pulse position in time.

3. The method according to claim 2, wherein said multipath response characteristic comprises a zero crossing point and wherein said first pulse is positioned at said zero crossing point.

4. The method according to claim 3, wherein said zero crossing minimizes coupling between said first pulse and said second pulse.

5. The method according to claim 2, wherein said multipath response characteristic comprises a maximum response point and wherein said first pulse is positioned at said maximum response point.

6. The method according to claim 5, wherein the signal of said first pulse is enhanced by the multipath signal of said second pulse.

7. The method according to claim 1, further comprising the steps of:
transmitting said first pulse having said first pulse characteristic and said second pulse having said second pulse characteristic;
receiving said first pulse having said first pulse characteristic and said second pulse having said second pulse characteristic; and
separating the multipath response of said first pulse from said multipath response of said second pulse by solving simultaneous equations.

8. The method according to claim 1, wherein a pulse characteristic of said first and second pulse characteristic corresponds to a pulse amplitude characteristic.

9. The method according to claim 1, wherein a pulse characteristic of said first and second pulse characteristic corresponds to a pulse width characteristic.

10. The method according to claim 1, wherein a pulse characteristic of said first and second pulse characteristic corresponds to a pulse polarity characteristic.

11. The method according to claim 10, wherein said pulse polarity characteristic comprises whether a pulse is inverted.

12. The method according to claim 1, wherein a pulse characteristic of said first and second pulse characteristic corresponds to a pulse type characteristic.

13. The method according to claim 12, wherein said pulse type characteristic comprises at least one of:
a square wave pulse;
a sawtooth pulse;
a Haar wavelet pulse;
a gaussian monopulse;
a doublet pulse;
a triplet pulse; and
a set of wavelets.

14. A system, comprising:
a first transceiver capable of transmitting a first pulse, said pulse having a first pulse characteristic;
a second transceiver capable of receiving said transmitted first pulse having said first pulse characteristic;
said second tranceiver capable of determining multipath response characteristics of said received first pulse; and
said second transceiver capable of determining a second pulse characteristic of a second pulse based on said multipath response characteristic.

15. The system according to claim 14, wherein a pulse characteristic of said first and second pulse characteristic corresponds to a pulse position in time.

16. The system according to claim 15, wherein said multipath response characteristic comprises a zero crossing point and wherein said first pulse is positioned at said zero crossing point.

17. The system according to claim 16, wherein said zero crossing minimizes coupling between said first pulse and said second pulse.

18. The system according to claim 15, wherein said multipath response characteristic comprises a maximum response point and wherein said first pulse is positioned at said maximum response point.

19. The system according to claim 18, wherein the signal of said first pulse is enhanced by the multipath signal of said second pulse.

20. The system according to claim 14, wherein said second tranceiver is capable of separating the multipath response of said first pulse from said multipath response of said second pulse by solving simultaneous equations.

21. The method according to claim 14, wherein a pulse characteristic of at least one of said first and second pulse characteristic corresponds to a pulse amplitude characteristic.

22. The method according to claim 14, wherein a pulse characteristic of at least one of said first and second pulse characteristic corresponds to a pulse width characteristic.

23. The method according to claim 14, wherein a pulse characteristic of said first and second pulse characteristic corresponds to a pulse polarity characteristic.

24. The method according to claim 23, wherein said pulse polarity characteristic comprises whether a pulse is inverted.

25. The method according to claim 14, wherein a pulse characteristic of said first and second pulse characteristic corresponds to a pulse type characteristic.

26. The method according to claim 25, wherein said pulse type characteristic comprises at least one of:
a square wave pulse;
a sawtooth pulse;
a Hanr wavelet pulse;
a gaussian monopulse;
a doublet pulse;
a triplet pulse; and
a set of wavelets.

27. A method for separating the multipath responses of a plurality of pulses, comprising the steps of:
transmitting a plurality of pulses having predefined pulse characteristic, wherein a predefined pulse characteristic corresponds to a pulse position in time;
receiving the plurality of pulses in accordance with said predefined pulse characteristic;
determining cross coupling value for a first pulse relative to a second pulse; and
separating the multipath response of said first pulse from the multipath response of said second pulse using said at least one cross coupling value.

28. The method according to claim 27, wherein said cross coupling value is determined adaptively to maintain operation in the resence of scenario dynamics, wherein said scenario dynamics comprises motion of an object in the environment, motion of a transmitter, and motion of a receiver.

29. The method according to claim 27, wherein said plurality of pulses is subdivided into pulse groups interspersed with time periods without pulses.

30. The method according to claim 29, wherein a time period without pulses allows for the decay of multipath energy produced by the preceding pulse group.

31. The method according to claim 29, wherein said time periods without pulses allow for reception of pulses between transmissions of pulse groups.

32. A method for determining characteristics of a pulse comprising the steps of:
transmitting from a first transceiver, a pulse having a first pulse characteristic, wherein said pulse characteristic corresponds to a pulse position in time;
receiving at a second transceiver said transmitted pulse in accordance with said first pulse characteristic;
determining at said second transceiver a multipath response characteristic of said received pulse;
determining at said second transceiver a second pulse characteristic of said pulse using said multipath response characteristic, wherein a pulse characteristic corresponds to a pulse position in time;
communicating from said second transceiver to said first transceiver said second pulse characteristic of said pulse; and
transmitting from and receiving at said first and second transceiver a pulse having said second pulse characteristic.

33. A system, comprising:
a first transceiver capable of transmitting a pulse having a first pulse characteristic, wherein a pulse characteristic corresponds to a pulse position in time;
a second transceiver capable of receiving said transmitted pulse in accordance with said first pulse characteristic;
said second transceiver capable of determining multipath response characteristic of said received pulse;
said second transceiver capable of determining a second pulse characteristic of pulse using said multipath response characteristic, wherein a pulse characteristic corresponds to a pulse position in time;
said second transceiver capable of communicating said second pulse characteristic of said pulse to said first transceiver; and
said first and second transceiver capable of transmitting and receiving a pulse having said second pulse characteristic.

34. A method for determining a pulse characteristic, comprising the steps of:
transmitting from a first transceiver, a pulse having a first pulse characteristic, wherein said first pulse characteristic corresponds to a pulse position in time;
receiving at a second transceiver said transmitted pulse in accordance with said first pulse characteristic;
determining at said second transceiver a multipath response characteristic of said received pulse;
determining at said second transceiver a second pulse characteristic of said pulse using said multipath response characteristic, wherein said pulse characteristic corresponds to a pulse position in time;
transmitting from said second transceiver, a pulse having said second pulse characteristic;
searching for and receiving at said first transceiver said transmitted pulse having said second pulse characteristic;
transmitting from and receiving at said first and second transceiver at least one pulse having said second pulse characteristic.

35. A system, comprising:
a first transceiver capable of transmitting pulse having a first pulse characteristic, wherein said pulse characteristic corresponds to a pulse position in time;
a second transceiver capable of receiving said transmitted pulse in accordance with said first pulse characteristic, said second transceiver capable of determining a multipath response characteristic of said received pulse;
said second transceiver capable of determining a second pulse characteristic of said pulse using said multipath response characteristic, wherein said pulse characteristic corresponds to a pulse position in time;
said second transceiver capable of transmitting a pulse having said second pulse characteristic; and
said first transceiver capable of searching for and receiving said transmitted pulse having said second pulse characteristic, said first and second transceiver capable of transmitting and receiving a pulse having said second pulse characteristic.

36. A method for positioning a pulse, comprising the step of:
positioning said pulse in time based on the multipath response of a preceding pulse.
